(19) United States
(12) Patent Application Publication
(10) Pub. No.: US 2025/0362351 A1
(43) Pub. Date: Nov. 27, 2025

(54) METHOD FOR DETECTING A RISK OF MALFUNCTION THROUGH IMBALANCE OF A DEVICE FOR STORING ENERGY COMPRISING A SET OF LEVELS OF ELECTROCHEMICAL CELLS

(71) Applicant: SOCOMEC, Benfeld (FR)

(72) Inventors: Arnaud DELAILLE, La Ravoire (FR); Bramy PILIPILI MATADI, Chambéry (FR)

(73) Assignee: SOCOMEC, Benfeld (FR)

(21) Appl. No.: 18/874,888

(22) PCT Filed: Jul. 4, 2023
(86) PCT No.: PCT/EP2023/068390

§ 371 Date: Dec. 13, 2024

(30) Foreign Application Priority Data
Jul. 4, 2022 (FR) FR2206730

(51) Int. Cl. G01R 31/389; G01R 31/3835; H01M 10/42

(52) U.S. Cl. CPC G01R 31/389; G01R 31/3835; H01M 10/4285

(57) ABSTRACT

The invention relates to a method for detecting a risk of malfunction through imbalance of a device (1) for storing energy comprising a set of levels (2) electrically connected to one another in series and consisting of electrochemical cells (3) electrically connected to one another in parallel, characterised in that it comprises:
a step (E2) of determining a first function (f1) characterising a correct operation of at least one level,
a step (E3) of determining a second function (f2) characterising the operation of a level having the lowest voltage at its terminals out of the set of levels of the device (1) for storing energy,
a step (E4) of calculating a difference between the first function (f1) and the second function (12), and then
a step (E5) of comparing the difference with a threshold, or several thresholds.

### TECHNICAL FIELD OF THE INVENTION

The invention relates to the technical field of the monitoring of devices for storing energy comprising a set of levels of electrochemical cells, the levels being electrically connected in series, each level comprising one to several electrochemical cells in parallel, in particular, cells of the lithium-ion type. More specifically, the invention relates to a method for detecting a risk of malfunction through imbalance between the series levels of such a device for storing energy. The invention also relates to monitoring equipment configured to implement such a detection method.

### PRIOR ART

Certain devices for storing energy comprise a set of levels of electrochemical cells, in particular, of the lithium-ion type, electrically connected in series in order to obtain a required target voltage, each level comprising one or more electrochemical cells electrically connected in parallel in order to obtain a required target capacity. For different reasons, an imbalance in the state of charge, commonly referred to as the SOC or State-of-Charge, may appear between the levels in series. This imbalance is commonly referred to as a “cell imbalance”. Possible reasons include problems of dispersion of the state of charge during the assembly of the cells, dispersion problems regarding self-discharge, capacity, or resistance between the cells, which may themselves be the consequence of dispersion problems regarding the manufacture of the cells, or dispersion problems regarding the conditions of use in operation resulting in different ageing kinetics. On observation, these imbalances are most often corrected by an electronic balancing system. However, it is possible that the imbalance is such that it cannot be compensated.

This imbalance may then cause a level to prematurely reach its maximum charging capacity, respectively its maximum discharge, before the other levels in series. If the level continues to be charged after it has reached its maximum charging capacity, respectively its maximum discharge capacity, this may result in an overcharge, respectively an under-discharge. These conditions may induce undesirable heating of the series level concerned, cause thermal runaway, or even the entire device for storing energy catching fire.

To detect a risk of imbalance of an electrochemical level of a device for storing energy, the most common method is based on observing the voltage at the terminals of each level in series during a full charge or discharge of the electrochemical storage system. The level of electrochemical cells with a risk of imbalance, or already imbalanced, generally has a voltage at its terminals that is significantly different from the voltage at the terminals of the other levels and may thus be identified.

However, this method does have some disadvantages. The voltage differences observed are themselves dependent on the conditions of use, namely the temperature, and charge and discharge current. These observed voltage differences are also a result of the states of charge and states of health, commonly referred to as the SOH or State-of-Health, recorded at the time of their observation. Lastly, differences in state of charge do not necessarily result in differences in voltage, in particular, in the case of Lithium Iron Phosphate (LFP) batteries, i.e., batteries based on iron phosphate at the positive electrode, which have a very stable voltage value over a wide operating range, in other words, over a wide range of state of charge. This method thus appears, in practice, to be difficult to calibrate to avoid false alarms, or even insufficient in certain configurations.

On the other hand, the voltage differences between levels are sometimes too small or become sufficiently large only very late in the conditions of use, and that may then lead to a safety problem once detected. Thus, when a risk of imbalance is detected by this means, it is generally necessary to urgently interrupt the use of the device for storing energy; this greatly disrupts the various equipment connected to it. As a result, state-of-the-art detection methods do not provide simple, smooth maintenance management of devices for storing energy.

State of health indicators are also known, which provide an indicator of the state of ageing of a device for storing energy or of a level composing the device for storing energy. Such indicators are complex to calculate and do not make it possible to detect a risk of malfunction through imbalance of at least one level of electrochemical cells composing the device for storing energy.

At the same time, with the widespread use of equipment incorporating energy storage units, notably motor vehicles incorporating lithium-ion batteries, there is an increasing quantity of so-called second-life energy storage units, which may be used for stationary energy storage, notably, to store electrical energy produced by an intermittent energy production source (e.g., solar or wind power) having a view to gradually supplying this energy. These different energy storage units are assembled and electrically connected together in order to form a device for storing energy having a larger capacity. Because the energy storage units which comprise such energy storage devices may have different levels of use, wear or age, the risk of observing an imbalance between the energy storage units is particularly high.

### PRESENTATION OF THE INVENTION

The aim of the invention is to provide a method for detecting a risk of malfunction through imbalance of a device for storing energy comprising a set of levels of electrochemical cells, the levels being electrically connected in series, the detection method overcoming the above-mentioned disadvantages and improving the detection methods known from the prior art.

More precisely, a first aim of the invention is to provide a method for the early detection of a risk of malfunction through imbalance of a device for storing energy.

A second aim of the invention is to provide a method for detecting a risk of malfunction through imbalance that may be implemented during partial charges and/or discharges of the device for storing energy.

### SUMMARY OF THE INVENTION

The invention relates to a method for detecting a risk of malfunction through imbalance of a device for storing energy comprising a set of levels electrically connected to one another in series and consisting of electrochemical cells electrically connected to one another in parallel, the detection method comprising:
a step of determining a first function characterising a correct operation of at least one level, the first function defining a relationship between, on the one hand, a magnitude relative to a quantity of charges circulating in at least one level and, on the other hand, a time elapsed during charging or discharging of at least one level,
a step of determining a second function characterising the operation of a level having the lowest voltage at its terminals among all of the levels of the device for storing energy, the second function defining a relationship between, on the one hand, said magnitude relative to a quantity of charges circulating in the level having the lowest voltage at its terminals among all of the levels of the device for storing energy and, on the other hand, a time elapsed during a charge or discharge of the level having the lowest voltage at its terminals, and then
a step of calculating a difference between said first function and said second function, and then
a step of comparing said difference with a threshold.

The first function may define a relationship between, on the one hand, a mean throughout all of the levels of the device for storing energy of a magnitude relative to a quantity of charges circulating in each level and, on the other hand, a time elapsed during a charge or discharge of all of the levels of the device for storing energy.

Said magnitude relative to a quantity of charges circulating in a level may be an incremental capacity of this level.

The step of calculating a difference between said first function and said second function may comprise a sub-step of calculating an integral value of a difference between the first function and the second function.

The step of calculating a difference between said first function and said second function may comprise:
a sub-step of estimating an extremum reached by the first function,
a sub-step of estimating an extremum reached by the second function, and then
a sub-step of calculating a difference between the extremum reached by the first function and the extremum reached by the second function.

The step of calculating a difference between said first function and said second function may comprise:
a sub-step of detecting an extremum reached by the first function,
a sub-step of estimating a charging or discharging time, at the end of which, the first function reaches its extremum,
a sub-step of detecting an extremum reached by the second function,
a sub-step of estimating a charging or discharging time, at the end of which, the second function reaches its extremum,
a sub-step of calculating a difference between the charging or discharging time, at the end of which, the first function reaches its extremum, and the charging or discharging time, at the end of which, the second function reaches its extremum.

The step of calculating a difference between said first function and said second function may comprise:
a sub-step of calculating a mean charge current of the device for storing energy between an instant at which the first function reaches its extremum, and a time at which the second function reaches its extremum, and then
a sub-step of calculating an imbalance in the state of charge, via the formula:

$$D\_SOC = D\_T \times 1 U\_mea / Q ,$$

where:
D_SOC denotes the imbalance in the state of charge,
D_T denotes the difference between the charging or discharging time, at the end of which, the first function reaches an extremum and the charging or discharging time, at the end of which, the second function reaches a corresponding extremum,
I_mea denotes the mean charge current, and
Q denotes the total remaining capacity of the level of the cells in question,
   and then:
a step of comparing said imbalance in the state of charge with a threshold.

The step of calculating a difference between said first function and said second function may comprise:
a sub-step of estimating a first extremum reached through the first function,
a sub-step of estimating at least one second extremum reached through the first function,
a sub-step of estimating a charging or discharging time, at the end of which, the first function reaches its first extremum,
a sub-step of estimating a charging or discharging time, at the end of which, the first function reaches its second extremum,
a sub-step of estimating a first extremum reached by the second function,
a sub-step of estimating at least one second extremum reached by the second function,
a sub-step of estimating a charging or discharging time, at the end of which, the second function reaches its first extremum,
a sub-step of estimating a charging or discharging time, at the end of which,
the second function reaches its second extremum,
and then:
a sub-step of calculating a difference between the first extremum of the first function and the first extremum of the second function, and/or
a sub-step of calculating a difference between the second extremum of the first function and the second extremum of the second function, and/or
a sub-step of calculating a difference between the charging or discharging time, at the end of which, the first function reaches its first extremum, and the charging or discharging time, at the end of which, the second function reaches its first extremum, and/or
a sub-step of calculating a difference between the charging or discharging time, at the end of which, the first function reaches its second extremum, and the charging or discharging time, at the end of which, the second function reaches its second extremum.

Said first function and/or said second function may be determined:
either during a charging or discharging phase of the device for storing energy according to a slow rate, in particular, a rate of less than or equal to C/5,
or during a phase for charging or discharging the device for storing energy according to a fast rate, in particular, a rate strictly greater than C/5, the step (E2, E3) of determining the first function and/or the second function then comprising a sub-step of filtering the magnitude relative to a quantity of charges circulating in a level.

The step of comparing said difference with a threshold may comprise:
a sub-step of comparing said difference with a first threshold and to a second threshold, the second threshold being strictly greater than the first threshold, and then
a sub-step of recording a first warning signal indicating a moderate risk, if said difference is greater than or equal to the first threshold and strictly less than the second threshold, and
a sub-step of recording a second warning signal indicating a high risk, if said difference is greater than or equal to the second threshold.

The first threshold may be determined as a function of an observed dispersion of said difference, and the second threshold may be determined as a function of a permissible overcharge through at least one electrochemical cell level of the device for storing energy.

The invention also relates to equipment for monitoring a device for storing energy comprising a set of electrochemical levels electrically connected in series, the monitoring equipment comprising hardware and software means configured to implement the method for detecting a risk of malfunction through imbalance of the device for storing energy, as defined above.

### PRESENTATION OF THE FIGURES

These objects, features and advantages of the present invention will be discussed in detail in the following description of a particular non-limiting embodiment i in relation to the accompanying figures, among which:

FIG. 1 is a schematic view of a device for storing energy to which monitoring equipment is connected according to one embodiment of the invention.

FIG. 2 is a block diagram of a method for detecting a risk of malfunction through imbalance of a device for storing energy according to an embodiment of the invention.

FIG. 3 is a graph showing the incremental capacitance of different levels of the device for storing energy as a function of the time elapsed during a charge of the device for storing energy.

FIG. 4 is a graph showing the incremental capacitance of the different levels of the device for storing energy as a function of the voltage at the terminals of these levels during a charge of the device for storing energy.

### DETAILED DESCRIPTION

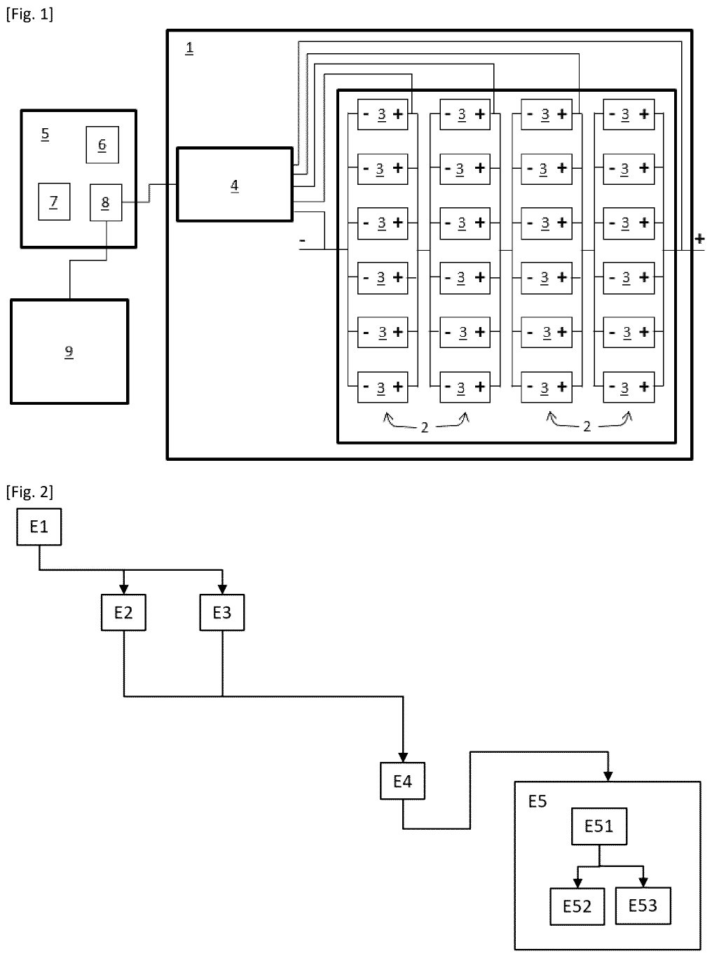

FIG. 1 schematically illustrates a device for storing energy 1 comprising a set of electrochemical cell levels 2 electrically connected to one another. The levels 2 are electrically connected in series. Each level 2 may comprise one or more electrochemical cells 3, also called “accumulators” or “rechargeable batteries”, electrically connected to one another in series and/or in parallel. Each cell 3 comprises one positive electrode, or cathode, and one negative electrode, or anode. The cathodes of the different cells 3 are directly or indirectly connected to a positive terminal of a level 2. Similarly, the anodes of the different cells 3 are connected directly or indirectly to a negative terminal of a level 2. The positive and negative terminals of each level 2 are respectively connected, directly or indirectly, to a positive and negative terminal of the device for storing energy 1. The different levels can be removably assembled in the device for storing energy, so that they can be removed and/or replaced.

According to the embodiment illustrated in FIG. 1, the device for storing energy 1 comprises four levels 2 electrically connected in series. Each level 2 comprises six cells 3, electrically connected in parallel. In a variant, the number of levels 2 and/or cells 3 may be different. Advantageously, all levels 2 comprise an identical number and arrangement of cells 3. Thus, they may comprise substantially identical theoretical modes of operation, in particular, voltages at their terminals and a capacitance, which are comparable.

The levels 2 and/or the cells 3 composing the device for storing energy 1 may optionally be respectively so-called second-life levels and/or cells, i.e., levels and/or cells resulting from a re-manufacturing process after having been integrated into a first system. For example, the device for storing energy 1 may be composed of a set of electric or hybrid automotive vehicle batteries. These batteries may have been used to store energy for the propulsion of the vehicle during its first service life, and then have been disassembled to be reused for a second time, whilst the vehicle was in operation. The device for storing energy 1 may be intended to store electrical energy produced by an intermittent source of energy production (for example, solar or wind energy).

The cells 3 composing the device for storing energy 1 are preferably cells of the lithium-ion type. In such cells, lithium ions may be reversibly exchanged between the positive electrode and the negative electrode. All of the cells 3 of the same device for storing energy 1 preferably have the same chemical composition. The negative electrode may comprise a graphite-based (LixC6) material or a lithium titanate-based (LTO) material. The positive electrode may be based on one of the following materials:
Lithium Iron Phosphate (LFP),
Lithium Nickel Manganese Cobalt Oxide (NMC),
Lithium Cobalt Oxide (LCO),
Lithium Nickel Cobalt Aluminium Oxide (NCA),
a mixture of Lithium Cobalt Oxide and Lithium Nickel Cobalt Aluminium Oxide (Blend LCO-NCA).

In a variant, the cells 3 composing the device for storing energy 1 may be of the sodium-ion type. In any event, the various cells 3 and the levels 2 which comprise the cells 3 are intended to operate in a balanced manner. The imbalance of a level 2 may lead to performance losses, or even thermal runaway of this level and therefore to a malfunction of the device for storing energy 1.

The device for storing energy 1 also comprises an electronic control system 4, commonly referred to as a BMS (acronym for “Battery Management System”), that is configured to control the state and/or the operation of the device for storing energy 1. The electronic control system 4 may be configured to control each cell 3 individually or a set of cells 3 connected together in the form of a level 2. In particular, according to the embodiment presented, the electronic control system 4 is configured for determining and/or measuring the following data:
a mean voltage U_mea, equal to the mean of the voltages at the terminals of the different levels 2;
a minimum voltage U_min, equal to the voltage at the terminals of level 2 having the lowest voltage among all levels 2;
a maximum voltage U_max, equal to the voltage at the terminals of level 2 having the highest voltage among all levels 2;
a charging or discharging electric current I circulating through the device for storing energy 1.

Advantageously, a large majority of the batteries or energy storage units produced or in use throughout the world comprise an electronic control system 4 that is already configured to provide this data. To implement the invention, it is therefore not necessary to modify the existing electronic control systems 4.

It must be noted that because the different levels 2 are assembled in series, the electric current circulating through the device for storing energy 1 is equal to the electric current circulating through each of the levels 2. In addition, the electronic control system 4 may also be configured to provide other data including the voltage at the terminals of each level of the device for storing energy 1, the state of charge of the device for storing energy 1 (commonly referred to as SOC), the state of health of the device for storing energy 1 (commonly referred to as SOH), etc.

The electronic control system 4 is connected via a data exchange network to monitoring equipment 5, in accordance with one embodiment of the invention. The monitoring equipment 5 comprises, in particular a memory 6, a microprocessor 7, an input/output interface 8 configured to receive data from the electronic control system 4 and configured to communicate with a man-machine interface 9, for example, a computer equipped with a screen. The memory 6 is a data recording medium comprising instruction codes which, when executed by the microprocessor 7, lead the latter to implement a method for detecting a risk of malfunction through imbalance of the device for storing energy 1, in accordance with one embodiment of the invention.

The monitoring equipment 5 may be connected to the electronic control system 4 via a data exchange network, such as the Internet. In a variant, the monitoring equipment 5 may be integrated into a housing connected to the electronic control system 4 through a direct wired link, or even be integrated into the electronic control system 4.

A first embodiment of a method for detecting a risk of malfunction through imbalance of the device for storing energy 1 according to the invention will now be described. The method is based on data calculated or measured, through the electronic control system 4, during a charging or discharging phase of the energy storage unit 1. Advantageously, the method does not require full charging or discharging the device for storing energy 1. On the contrary, only one charge or one partial discharge is sufficient to implement the process. For example, the method may be implemented during a charge or discharge, in which the state of charge of the device for storing energy 1 varies between 25% and 75% of its total charging capacity. The determination method may consist of five steps E1, E2, E3, E4, E5, shown schematically in FIG. 2.

In a first step, E1, the electronic control system 4 transmits to the monitoring equipment 5, the values of the following quantities:
the voltage U_min of the level 2 having the lowest voltage,
the voltage U_max of the level 2 having the highest voltage,
the mean voltage U_mea at the terminals of the different levels,
the electric current I circulating in the device for storing energy.

These values may, for example, be transmitted in the form of time series, periodically and/or at the end of each charging or discharging phase of the device for storing energy 1.

In a second step E2, a first function f1 is determined, referred to as the reference function, characterising a correct operation of at least one level 2. The term “correct operation” is understood to mean a normal or nominal operation of at least one level 2, i.e., the operation of a non-malfunctioning level. According to the first embodiment, the first function f1 is equal to a mean function calculated on the basis of all of the levels of the device for storing energy 1. This first embodiment is therefore based on the hypothesis that the mean of all of the levels is representative of a correct operation. Defining the first function on the basis of a mean of all of the levels of the storage device makes it possible to make the detection method more robust, and in particular, to maintain effective detection even when one of the levels experiences an abnormally high voltage at its terminals. It may be agreed that this embodiment may be implemented only for a device for storing energy comprising a sufficient number of levels, so that the mean calculated throughout all of the levels reflects, according to the laws of statistics, a correct operation. Alternatively, and as will be seen later, other methods making it possible to determine the reference function may be proposed.

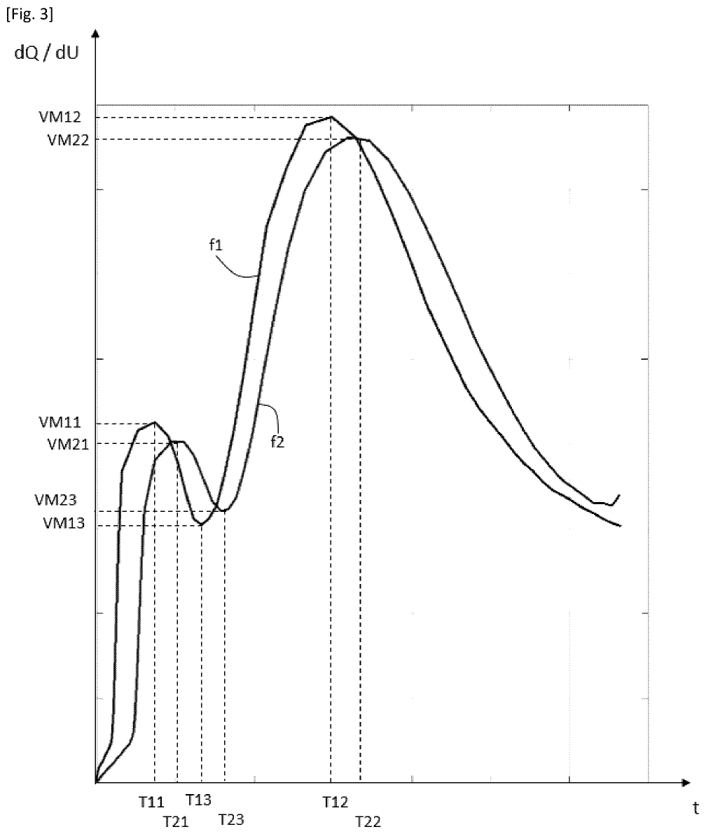

In general, the first function f1 is a mathematical function, representable on a graph, such as the graph in FIG. 3, and one that may be defined by a set of points. The first function defines a relationship between, on the one hand, a magnitude relative to a quantity of charges circulating in at least one level (shown on the y-axis in FIG. 3), and, on the other hand, a time elapsed during a charge or discharge of at least one level (shown on the x-axis in FIG. 3, and expressed, for example, in hours). In this case, the functions shown in FIG. 3 are representative of a charge of the device for storing energy: the state of charge increases when moving along the x-axis. These functions may therefore be determined during a charging phase of the device for storing energy. In a variant, these functions may also be calculated during discharges of the device for storing energy by reversing the orientation of the x-axis. Supposing that said magnitude relative to a quantity of charges circulating in at least one level changes sign in the discharging phases compared to the charging phases, an absolute magnitude of this quantity is advantageously used. Supposing that the first function f1 is equal to a mean function calculated on the basis of all of the levels, said at least one level corresponds to all of the levels of the device for storing energy 1.

According to a preferred embodiment, the magnitude relative to a quantity of charges circulating in at least one level is equal to an incremental capacitance (dQ/dU, expressed, for example, in Ampere-hours per volt) of at least one level. The incremental capacitance of a level is defined by a ratio of a charge quantity differential dQ of that level over a voltage differential dU at the terminals of that level. In a variant, the magnitude relative to a quantity of charge circulating in at least one level may be defined differently. It may, for example, be equal to dU/dQ, or to a function derived from dQ/dU or dU/dQ. This function may even be defined in such a way as to be independent of the voltage differential dU at the terminals of this level.

The first function f1 may be determined as follows: to begin with, a first intermediate function is calculated, defining a relationship between the electric current I circulating in the device for storing energy and the time elapsed during a charge or discharge period of the device for storing energy. Then, a second intermediate function is calculated, defining a relationship between a quantity of charges Q circulating in each level and the time elapsed by integrating the first intermediate function over the charge or discharge period considered. This second intermediate function is combined with a third intermediate function establishing a relationship between the mean voltage U_mea and the time elapsed. It is thus possible to calculate a fourth intermediate function defining a relationship between the quantity of charges Q circulating in each level and the mean voltage U_mea. Then, a fifth intermediate function is calculated by deriving the fourth intermediate function relative to the mean voltage U_mea. The fifth intermediate function is therefore a function of the type dQ/dU_mea=f(U_mea). Finally, this fifth intermediate function is combined with the third intermediate function establishing a relationship between the mean voltage U_mea and the time elapsed t so as to obtain the first function ft. The first function is therefore a function of the type dQ/dU_mea=f(t).

Alternatively, to determine the first function ft, it is possible to determine for each level, the function defining the relationship between the incremental capacitance of this level and the time elapsed. Then, it is possible to perform an arithmetic mean of the functions determined for each level. This method allows for more accurate detection but requires more computational resources because the calculations are repeated for each level of the device for storing energy. Furthermore, this method requires the electronic control system 4 to provide the voltage at the terminals of each level of the device for storing energy.

According to a variant embodiment of the second step E2, at least one level whose operation is correct may be defined as the level 2 whose voltage at its terminals is closest to the mean voltage of all of the levels 2 of the device for storing energy 1.

According to other variant embodiments of the second step E2, the first function may be defined differently, for example, by means of a theoretical function or by identifying by any means one or more levels of the device for storing energy 1 which is functioning correctly and by determining the relationship between the incremental capacitance circulating in this or these levels and the time elapsed during a charge or discharge.

Lastly, at the end of the second step E2, a first function f1 is obtained, representative of a normal operation of any one or more levels. This first function may be determined according to several different methods but which have the common feature of defining a relationship between, on the one hand, a magnitude relative to a quantity of charges circulating in a level and, on the other hand, a time elapsed during a charge or discharge of the device for storing energy. This first function is therefore a reference function and serves as a basis for comparison to determine whether a particular level presents a risk of malfunction through imbalance.

In a third step E3, a second function f2 is determined, intended to be compared with the previously defined first function. As for the first function f1, the second function f2 is a mathematical function, representable on a graph, such as the graph in FIG. 3, and that may be defined by a set of points. The third step E3 may be executed before or after the second step E2 or in parallel with the second step E2. The second function f2 defines a relationship between, on the one hand, the magnitude relative to a quantity of charges circulating in the level having the lowest voltage at its terminals among all of the levels of the device for storing energy and, on the other hand, a time elapsed during a charge or discharge of this level. In particular, according to the preferred embodiment, the magnitude relative to the quantity of charges circulating in the level having the lowest voltage at its terminals is equal to the incremental capacitance of this level.

The method for determining the second function f2 may be similar to the method for determining the first function f1. The second function f2 may be determined as follows: to begin, a first intermediate function is calculated, defining a relationship between the electric current I circulating in the device for storing energy and the time elapsed during a charge or discharge period of the device for storing energy. Then, a second intermediate function is calculated, defining a relationship between a quantity of charges Q circulating in the level having the lowest voltage at its terminals and the time elapsed by integrating the first intermediate function over the charge or discharge period. This second intermediate function is combined with a third intermediate function establishing a relationship between the minimum voltage U_min and the time elapsed. It is thus possible to calculate a fourth intermediate function defining a relationship between the quantity of charges Q circulating in the level having the lowest voltage at its terminals and the minimum voltage U_min. Then, a fifth intermediate function is calculated by deriving the fourth intermediate function relative to the minimum voltage U_min. The fifth intermediate function, therefore, is a function of the type dQ/dU_min=f(U_min). Finally, this fifth intermediate function is combined with the third intermediate function establishing a relationship between the mean voltage U_mea and the time elapsed so as to obtain the second function f2. The second function, therefore, is a function of the type dQ/dU_min=f(t).

In general, the graph on which the second function is representable is identical to the graph on which the first function is representable. In other words, the form of the first function is the same as the form of the second function so as to allow a comparison of these two functions.

It must be noted that the quantity of charges circulating in each level is calculated more precisely during a charging or discharging phase of the device for storing energy according to a slow rate, in particular, a rate of less than or equal to C/5, that is to say, having a charge current making it possible to completely recharge the device for storing energy in at least five hours. Alternatively, the quantity of charges circulating in each level may also be calculated during a charging or discharging phase of the device for storing energy according to a faster rate, in particular, a rate strictly greater than C/5. In this case, steps E2 and E3 for determining the first function and/or the second function advantageously comprise a sub-step of filtering the magnitude relative to a quantity of charges circulating in a level.

The first function f1 and the second function f2 are defined over a given charge or discharge period that may correspond to a partial charge or discharge of the device for storing energy. Thus, the period over which the first function f1 and the second function f2 are defined may be restricted compared with the total time required to fully charge or discharge the device for storing energy, having the same charging rate, from a state of charge of 0% in the case of a charge or respectively from a state of charge of 100% in the case of a discharge. For example, the period over which the first function f1 and the second function f2 are defined may be less than or equal to 75%, or even less than or equal to 50%, or even less than or equal to 25% of the total time. Preferably, the period over which the first function f1 and the second function f2 are defined is sufficient to identify at least one extremum of the first function and at least one extremum of the second function, even at least two extremums of the first function and at least two extremums of the second function, even three extremums of the first function and three extremums of the second function.

As is clearly visible in FIG. 3, when the period over which the first function f1 and the second function f2 are defined is sufficiently large, the first function f1 and the second function f2 have a specific aspect: each of these two functions successively reaches two maximum values, referenced VM11 and VM12 for the first function f1, and VM21 and VM22 for the second function f2. The maximum values VM11, VM12, VM21 and VM22 are reached at the end of a time T11, T12, T21 and T22, respectively. When the first function f1 and the second function f2 are established during a charge of the device for storing energy, the first maximum value VM11 reached by the first function is generally less than or equal to the second maximum value VM12 reached by the first function. Similarly, the first maximum value VM21 of the second function is generally less than or equal to the second maximum value VM22 of the second function. Moreover, an offset is observed between the first function f1 and the second function f2. In particular, the maximum values VM11 and VM12 of the first function are strictly greater than the maximum values VM21 and VM22 of the second function, respectively. In addition, the times T11 and T12 are strictly less than the times T21 and T22, respectively. Between its two maximum values VM11 and VM12, the first function f1 reaches a minimum value VM13 at the end of a time T13. Similarly, between its two maximum values VM21 and VM22, the second function f2 reaches a minimum value VM23 at the end of a time T23. It is noted that the minimum value VM13 is strictly less than the maximum value VM23 and that the time T13 is strictly less than the time T23. The two maximum values VM11 and VM12 and the minimum value VM13 constitute three extremums of the first function. Similarly, the two maximum values VM21 and VM22 and the minimum value VM23 constitute three extremums of the second function. In addition, it can also be seen that there are times when the first function is strictly greater than the second function and other instances when the first function is strictly less than the second function.

In a fourth step E4, a difference is calculated between said first function f1 and said second function f2. There are several ways for quantifying such a difference. According to a first embodiment, the fourth step E4 comprises a sub-step of calculating an integral value of a difference between the first function f1 and the second function f2. This integral calculation may, in particular, be performed over the entire period, over which the first function and the second function are defined. This calculation therefore substantially means calculating the area defined between the first function and the second function. Advantageously, the integral calculation may be based on an absolute value of the difference between the first function f1 and the second function f2. Thus, the integral calculation of the periods where the first function is strictly greater than the second function is added to the integral calculation of the periods where the first function is strictly less than the second function. It is thus possible to clearly highlight the differences between the first function and the second function, which makes it possible to improve the sensitivity of detection. An advantage of determining said difference on the basis of an integral calculation is that this method may be implemented over any charge or discharge period, comprising a charge or partial discharge period in which the functions f1 and/or f2 do not reach all of their extremums. Thus, the detection method makes it possible to detect an imbalance even when the device for storing energy undergoes incomplete charge and discharge cycles. Another advantage of determining said difference on the basis of an integral calculation is that this method makes it possible to detect a difference even when the maximum values VM11 and VM12 of the first function are substantially equal to the maximum values VM21 and VM22 of the second function (there is then only a time offset between the two functions f1 and f2). Similarly, this method makes it possible to detect a difference even when the times T11 and T12 are substantially equal to the times T21 and T22 of the second function (there is then only an amplitude offset between the two functions f1 and f2).

According to another embodiment of the fourth step E4, the difference between the first function f1 and the second function f2 may be calculated via an amplitude difference between these two functions. In this case, the fourth step comprises a sub-step of estimating at least one extremum (in particular, the values VM11, VM12 or VM13) reached by the first function, and a sub-step of estimating at least one extremum reached by the second function (respectively the values VM21, VM22 or VM23). Then, the fourth step E4 comprises a sub-step of calculating a difference between the extremum reached by the first function and the extremum reached by the second function. This difference is therefore equal to VM11−VM21, or VM12−VM22, or VM13−VM23. The difference may also be equal to a result calculated as a function of the three differences at VM11−VM21, VM12−VM22, and VM13−VM23, or equal to a result calculated as a function of two differences among these three differences.

Due to the similarity in aspect of the first function and the second function, it is advisable to compare the extremes VM11, VM12 and VM13 respectively with the extremes VM21, VM22 and VM23. The calculation of a difference between non-corresponding extremums would lead to an aberrant result that may be filtered so as not to base the method on such a comparison. The implementation of the fourth step E4 by comparing the maximum or minimum values reached by the first function and by the second function has the advantage of being economical in calculation and simple to implement.

According to another embodiment of the fourth step E4, the difference between the first function f1 and the second function f2 may be calculated via a time difference between the two functions f1 and f2. In this case, the fourth step comprises a sub-step of detecting an extremum VM11, VM12, VM13 reached by the first function f1 followed by a sub-step of estimating the charge or discharge time T11, T12, T13 at the end of which the first function reaches its extremum. Similarly for the second function: the fourth step comprises a sub-step of detecting an extremum VM21, VM23 reached by the second function, then a sub-step of estimating the time T21 T22, T23 of charging or discharging at the end of which the second function reaches its extremum. Then, at least one of the differences T11−T21, and/or T12−T22, and/or T13−T23 is calculated. The difference may thus be equal to T11−T21, or to T12−T22, or even to T13−T23. The difference may also be equal to a result calculated as a function of the three differences at T11−T21, T12−T22, and T13−T23, or equal to a result calculated as a function of two differences among these three differences. This alternative embodiment has the advantage of detecting an imbalance between the levels that mainly results in a time offset between the two functions. It is thus possible to detect an imbalance in the charging and discharging inertia of the different levels.

According to yet another variant embodiment of the fourth step, said difference between the first function and the second function may be equal to any result calculated as a function of all or some of the six differences VM11−VM21, VM12−VM22, VM13−T11−T21, T12−T22, and T13−T23.

In a fifth step E5, the difference calculated during the fourth step is compared with a threshold. Then, if the difference is strictly greater than said threshold, a signal may be saved in the memory 6 of the monitoring equipment 5. This signal may be read by the man-machine interface 9. Then, the man-machine interface 9 may generate an alert message indicating that a level of the device for storing energy presents a risk of malfunction through imbalance.

Advantageously, the comparison of functions defining a relationship between a magnitude relative to a quantity of charges circulating in a level and a time elapsed during a charge or a discharge of the device for storing energy makes it possible to detect, well in advance, a drift that indicates a risk of thermal runaway. Devices for storing energy 1 have thus been observed which on simple observation of the voltage at the terminals of the various levels have not made it possible to identify any anomaly several months before a malfunction has occurred. On the other hand, the implementation, according to the invention, of the method on this device for storing energy makes it possible to identify a risk of malfunction through imbalance several months before it occurs. In addition, the detection method generally makes it possible to identify the level of the device for storing energy responsible for this anomaly. The level in question may then easily be removed or replaced during any maintenance operation.

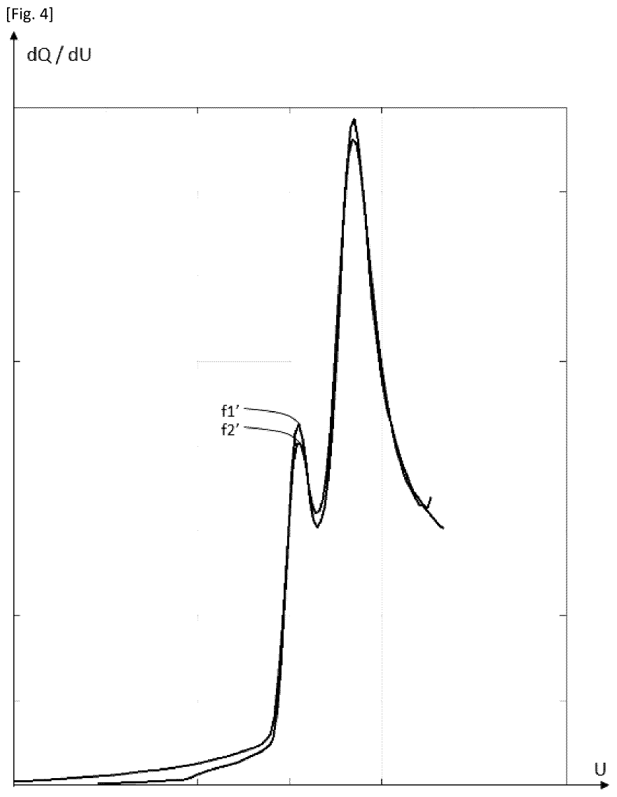

FIG. 4 comparatively illustrates two functions, f1′ and f2′, respectively characterising a correct operation of at least one level and the operation of a level having the lowest voltage at its terminals among all of the levels of the device for storing energy. The two functions f1′ and f2′ establish a relationship between an incremental capacitance dQ/dU (on the y-axis) and a voltage U at the terminals of the level concerned. The functions f1′ and f2′ are constructed on the basis of the same device for storing energy as previously described and during the same charging phase as that used to calculate the functions f1 and f2 shown in FIG. 3. It can be seen that the difference between the first function f1′ and f2′ in FIG. 4 is significantly less noticeable than the difference between the functions f1 and f2 in FIG. 3. In particular, the functions f1 and f2 are offset from one another both on the x-axis and on the y-axis while the functions f1′ and f2′ are offset only along the y-axis. Compared with a method based on functions establishing a relationship between the incremental capacitance and a voltage, the method that has just been described, based on functions establishing a relationship between the incremental capacitance and a charging or discharging time elapsed, makes it possible to better highlight a difference in behaviour between the different levels and therefore to detect a risk of malfunction at an early stage.

According to an improvement of the invention, the fifth step E5 may comprise:
a step E51 for comparing said difference with a first threshold and with a second threshold, the second threshold being strictly greater than the first threshold, and then
a step E52 for recording a first warning signal indicating a moderate risk, if said difference is greater than or equal to the first threshold and strictly less than the second threshold, and
a step E53 for recording a second warning signal indicating a high risk, if said difference is greater than or equal to the second threshold.
The warning signal and the second signal are intended to be saved in the memory 6 of the monitoring equipment 5. These signals may then be consulted by the man-machine interface 9 in order to produce an alert message adapted to the situation.

Advantageously, the first threshold is determined as a function of a normal dispersion of said magnitude relative to a quantity of charges circulating in a level. For example, this first threshold may be determined experimentally by observing correctly functioning levels in a device for storing energy. The first threshold may thus be defined as equal to or slightly greater than the largest difference (as calculated in step E4) observed over a sufficiently long period, with a device for storing energy in which all of the levels operate correctly. The first threshold may also correspond to a threshold beyond which the electronic control system 4 may no longer compensate for imbalances between the different levels of the device for storing energy.

The second threshold may be determined as a function of a permissible overcharge through at least one electrochemical cell level of the device for storing energy. The permissible overcharge refers to the percentage of charges which a level is capable of supporting before irreversible degradation. In other words, if this difference exceeds the permissible overcharge, then thermal runaway will definitely occur. The second threshold may therefore advantageously be defined as a fraction of the permissible overcharge.

According to another improvement of the invention, the fourth step E 4 may comprise a sub-step of calculating a mean charge current 1U_mea of the device for storing energy between the instant when the first function f 1 reaches one of the extremes VM 11, VM 12, VM 13 and the instant when the second function f 2 reaches one of the corresponding extremes VM 21, VM 22, VM 23. Preferably, the charge current I (the value of which is supplied by the electronic control system 4) is substantially constant between these two instances and the mean charge current 1U_mea is equal to this value. In a variation, the charge current I may undergo certain variations between these two instances and, in this case, a time mean may be calculated. Then, the fourth step E4 may comprise a sub-step of calculating a variation in state of charge D_SOC by means of a multiplication of the difference between the time T11, T12, T13 of charging or discharging, at the end of which, the first function reaches one of its extremums and the time T21, T22, T23 of charging or discharging, at the end of which, the second function reaches the corresponding extremum VM21, VM22, VM23 having the mean charge current 1_mea. In other words, the imbalance in the state of charge D_SOC may be calculated using the following formula:

D_SOC=D_T×1U_mea/Q

where Q denotes the total remaining capacity of the cell level concerned, i.e., the total capacity of the level considered during the implementation of the method, and where D_T is equal to the result of the subtraction T11−T21 or T12−T22 or T13−T23. Thus, the imbalance in the state of charge D_SOC is equal to a ratio between two charge quantities and may be expressed as a percentage. Then, during a fifth step E5, the imbalance in the state of charge D_SOC may be compared with a threshold, or with several thresholds to quantify the level of criticality of the signal. In particular, the imbalance in the state of charge D_SOC may be compared to a first threshold and to a second threshold, as explained previously. The first threshold may be, for example, between 5% and 20%. The second alert threshold, strictly greater than the first alert threshold, may be between 20% and 40%, for example.

Lastly, thanks to the invention, there is a method for early detection of a risk of malfunction through imbalance of a level of a device for storing energy that may be implemented during partial charges and/or discharges. Compared to known methods, this method makes it possible to detect an imbalance at an early stage, that allows better maintenance of the device for storing energy. In particular, the method makes it possible to detect imbalances which were previously difficult to detect, in particular, imbalances caused by a state of charge (SOC) deviation on chemistries which do not have a significant relationship between voltage and state of charge (SOC), such as an LFP Li-ion chemistry, or caused by a state of health (SOH) deviation of the various levels of the device for storing energy.

The invention has the advantage of not requiring any prior characterisation of the device for storing energy or a similar device for storing energy. Indeed, according to the invention, said function characterising a correct operation of at least one level is established directly with the device for storing energy for which it is sought to detect a risk of malfunction through imbalance. According to the invention, the operation of the level having the lowest voltage at its terminals is compared with the operation of other levels of the same device for storing energy. The method according to the invention is therefore much simpler to implement than the detection methods previously known. The method may be implemented on any device for storing energy comprising a set of levels electrically connected to one another in series, without characterisation or calculation of a good theoretical operation of this device for storing energy. The monitoring equipment implementing the detection method according to the invention is thus “plug-and-play”, i.e., it is functional as soon as it is connected to the electronic control system of a device for storing energy.

1. A method for detecting a risk of malfunction through imbalance of a device for storing energy (1) comprising a set of levels (2) electrically connected to one another in series and consisting of electrochemical cells (3) electrically connected to one another in parallel, characterised in that it comprises:
a step (E2) of determining a first function (f1) characterising a correct operation of at least one level, the first function defining a relationship between, on the one hand, a magnitude relative to a quantity of charges circulating in at least one level and, on the other hand, a time elapsed during a charge or discharge of at least one level,
a step (E3) of determining a second function (f2) characterising the operation of a level having the lowest voltage at its terminals among all of the levels of the device for storing energy (1), the second function defining a relationship between, on the one hand, said magnitude relative to a quantity of charges circulating in the level having the lowest voltage at its terminals among all of the levels of the device for storing energy and, on the other hand, a time elapsed during a charge or discharge of the level having the lowest voltage at its terminals, and then
a step (E4) of calculating a difference between said first function (f1) and said second function (f2), and then
a step (E5) of comparing said difference with a threshold.

2. The detection method according to claim 1, characterised in that the first function (f1) defines a relationship between, on the one hand, a mean throughout all of the levels of the device for storing energy of a magnitude relative to a quantity of charges circulating in each level and, on the other hand, a time elapsed during a charge or discharge of all of the levels of the device for storing energy.

3. The detection method according to claim 1, characterised in that said magnitude relative to a quantity of charges circulating in a level is an incremental capacitance of this level.

4. The detection method according to claim 1, characterised in that the step (E4) for calculating a difference between said first function and said second function comprises a sub-step of calculating an integral magnitude of a difference between the first function (f1) and the second function (f2).

5. The detection method according to claim 1, characterised in that the step (E4) for calculating a difference between said first function (f1) and said second function (f2) comprises:
a sub-step of estimating an extremum (VM11, VM12, VM13) reached by the first function,
a sub-step of estimating an extremum (VM21, VM22, VM23) reached by the second function, and then
a sub-step of calculating a difference between the extremum (VM11, VM12, VM13) reached by the first function and the extremum (VM21, VM22, VM23) reached by the second function.

6. The detection method according to claim 1, characterised in that the step (E4) for calculating a difference between said first function (f1) and said second function (f2) comprises:
a sub-step of detecting an extremum (VM11, VM12, VM13) reached by the first function (f1),
a sub-step of estimating a charging or discharging time (T11, T12, T13), at the end of which, the first function reaches its extremum (VM11, VM12, VM13),
a sub-step of detecting an extremum (VM21, VM22, VM23) reached by the second function (f2),
a sub-step of estimating a charging or discharging time (T21 T22, T23), at the end of which, the second function reaches its extremum (VM21, VM22, VM23),
a sub-step of calculating a difference between the charging or discharging time (T11, 112, T13), at the end of which, the first function reaches its extremum and the charging or discharging time (T21, T22, T23), at the end of which, the second function reaches its extremum (VM21, VM22, VM23).

7. The detection method according to claim 6, characterised in that the step (E4) for calculating a difference between said first function (f1) and said second function (f2) comprises:
a sub-step of calculating a mean charge current of the device for storing energy between an instant at which the first function reaches its extremum (VM11, VM12, VM13), and a time at which the second function reaches its extremum (VM21, VM22, VM23), and then
a sub-step of calculating an imbalance in the state of charge, via the formula:
$$D\_SOC = D\_T \times 1 U\_mea / Q ,$$
where:
D_SOC denotes the imbalance in the state of charge,
D_T denotes the difference between the charging or discharging time (T11, T12, T13), at the end of which, the first function reaches an extremum and the charging or discharging time (T21, T22, T23), at the end of which, the second function reaches a corresponding extremum (VM21, VM22, VM23),
l_mea denotes the mean charge current, and
Q denotes the total remaining capacity of the level of the cells in question,
and then:
a step (E5) of comparing said imbalance in the state of charge with a threshold.

8. The detection method according to claim 1, characterised in that the step (E4) for calculating a difference between said first function (f1) and said second function (f2) comprises:
a sub-step of estimating a first extremum (VM11) reached by the first function,
a sub-step of estimating at least one second extremum (VM12, VM13) reached by the first function,
a sub-step of estimating a charging or discharging time (T11), at the end of which, the first function reaches its first extremum (VM11),
a sub-step of estimating a charging or discharging time (T12, T13), at the end of which, the first function reaches its second extremum (VM12, VM13),
a sub-step of estimating a first extremum (VM21) reached by the second function,
a sub-step of estimating at least one second extremum (VM22, VM23) reached by the second function,
a sub-step of estimating a charging or discharging time (T21), at the end of which, the second function reaches its first extremum (VM21),
a sub-step of estimating a charging or discharging time (T22, T23), at the end of which, the second function reaches its second extremum (VM22, VM23),
and then:
a sub-step of calculating a difference between the first extremum (VM11) of the first function and the first extremum (VM21) of the second function, and/or
a sub-step of calculating a difference between the second extremum (VM12, VM13) of the first function and the second extremum (VM22, VM23) of the second function, and/or
a sub-step of calculating a difference between the charging time (T11) or discharging time, at the end of which, the first function reaches its first extremum (VM11), and the charging time (T21) or discharging time, at the end of which, the second function reaches its first extremum (VM21), and/or
a sub-step of calculating a difference between the charging time (T12, T13) or discharging time, at the end of which, the first function reaches its second extremum (VM12, VM13), and the charging time (T22, T23) or discharging time, at the end of which, the second function reaches its second extremum (VM21).

9. The detection method according to claim 1, characterised in that said first function (f1) and/or said second function (f2) are determined:
either during a charging or discharging phase of the device for storing energy according to a slow rate, in particular, a rate of less than or equal to C/5,
or during a phase for charging or discharging the device for storing energy according to a fast rate, in particular, a rate strictly greater than C/5, the step (E2, E3) of determining the first function and/or the second function then comprising a sub-step of filtering the magnitude relative to a quantity of charges circulating in a level.

10. The detection method according to claim 1, characterised in that the step (E5) for comparing said difference with a threshold comprises:
a sub-step (E51) for comparing said difference with a first threshold and with a second threshold, the second threshold being strictly greater than the first threshold, and then
a sub-step (E52) for recording a first warning signal indicating a moderate risk, if said difference is greater than or equal to the first threshold and strictly less than the second threshold, and
a sub-step (E53) for recording a second warning signal indicating a high risk, if said difference is greater than or equal to the second threshold.

11. The detection method according to claim 10, characterised in that the first threshold is determined as a function of an observed dispersion of said difference, and in that the second threshold is determined as a function of a permissible overcharge by at least one level of electrochemical cells of the device for storing energy.

12. The monitoring equipment (5) of a device for storing energy (1) comprising a set of electrochemical levels (2) electrically connected in series, characterised in that it comprises hardware (6, 7, 8) and software means configured to implement the method for detecting a risk of malfunction through imbalance of the device for storing energy according to claim 1.
